(19) United States
(12) Patent Application Publication
(10) Pub. No.: US 2011/0229660 A1
(43) Pub. Date: Sep. 22, 2011

(54) ION BEAM ASSISTED DEPOSITION OF OPHTHALMIC LENS COATINGS

(76) Inventor: Timothy Ray Reynolds, Williamsburg, OH (US)

(21) Appl. No.: 13/050,740

(22) Filed: Mar. 17, 2011

Related U.S. Application Data
(60) Provisional application No. 61/316,304, filed on Mar. 22, 2010.
(60) Provisional application No. 61/348,425, filed on May 26, 2010.

(51) Int. Cl. C23C 16/48; C23C 16/40; C23C 16/52

(52) U.S. Cl. 427/595

(57) ABSTRACT

Some embodiments provide a physical vapor deposition process for forming a coating on a substrate of an ophthalmic lens in a vacuum deposition chamber. The process can include depositing a multilayer interference stack having a plurality of low refractive index layers and a plurality of high refractive index layers on the substrate by: depositing one or more of the plurality of high refractive index layers by contacting the substrate with a vapor phase pulse of one or more high refractive index source chemicals simultaneously while contacting the substrate with an energetic ion beam generated by an ion source; and depositing each of the plurality of low refractive index layers by contacting the substrate with a vapor phase pulse of one or more low refractive index source chemicals.

### RELATED APPLICATIONS

This application claims the benefit under 35 U.S.C. §119(e) of U.S. Provisional Patent Application Ser. No. 61/316,304, filed Mar. 22, 2010, titled ION BEAM ASSISTED DEPOSITION OF OPHTHALMIC LENS COATINGS, and of U.S. Provisional Patent Application Ser. No. 61/348,425, filed May 26, 2010, titled ION BEAM ASSISTED DEPOSITION OF OPHTHALMIC LENS COATINGS. The entire contents of each of these applications are incorporated by reference herein and made a part of this specification.

### BACKGROUND

1. Field

This disclosure relates to coatings for optical devices and in particular to coatings for lenses used in eyewear.

2. Description of Related Art

When light moves between media of differing refractive indices, both reflection and refraction of the light may occur. The reflection of light in such circumstances can produce glare, decrease the brightness of transmitted light, reduce the contrast of a transmitted image, and produce other effects that can be disadvantageous. A coating can be applied to the surface of a lens or other optical device in order to change one or more optical properties of the device. For example, an antireflective coating (ARC) can reduce surface reflections that occur at one or more interfaces between the lens and air.

### SUMMARY

Example embodiments described herein have several features, no single one of which is indispensable or solely responsible for their desirable attributes. Without limiting the scope of the claims, some of the advantageous features of some embodiments will now be summarized.

Some embodiments provide a physical vapor deposition process for forming a coating on a substrate of an ophthalmic lens in a vacuum deposition chamber. The process can include depositing a multilayer interference coating having a plurality of low refractive index layers and a plurality of high refractive index layers on the substrate. The interference coating can be formed by depositing each of the plurality of high refractive index layers by contacting the substrate with a vapor phase pulse of one or more high refractive index source chemicals while simultaneously contacting the substrate with an energetic ion beam, such that each of the deposited plurality of high refractive index layers can include a substantially fully oxidized metal oxide thin film. Each of the plurality of low refractive index layers can be deposited by contacting the substrate with a vapor phase pulse of one or more low refractive index source chemicals, such that the deposited plurality of low refractive index layers are arranged in an alternating relationship with the deposited plurality of high refractive index layers. The thicknesses of the plurality of high refractive index layers and the plurality of low refractive index layers can be selected such that, when the multilayer interference coating is deposited on a surface of an ophthalmic lens, luminous reflectance at the surface of the ophthalmic lens is less than or equal to about 2% using CIE illuminant D₆₅. In certain embodiments, each of the plurality of low refractive index layers is deposited without using ion beam assisted deposition.

The process can include depositing a hardening layer of silica having a first thickness on the substrate, wherein the hardening layer is disposed between the multilayer interference coating and the ophthalmic lens. The first thickness can be greater than or equal to about 150 nm, greater than or equal to about 250 nm, or greater than or equal to about 300 nm. In some embodiments, the one or more low refractive index source chemicals include a material having a visible light refractive index less than or equal to about 1.5. The one or more low refractive index source chemicals can include silica.

The one or more high refractive index source chemicals can include at least one of zirconium oxide, niobium oxide, titanium oxide, tantalum oxide, cerium oxide, or hafnium oxide. The energetic ion beam can be generated by a suitable ion source, such as, for example, an End Hall ion source. The End Hall ion source can emit a beam of ions having a suitable average energy level. In some embodiments, a suitable average energy level can be at least about 50 eV and/or less than or equal to about 120 eV.

In some embodiments, the process can include depositing an adhesor layer between the antireflection coating and the ophthalmic lens. A hardening layer can be deposited between the antireflection coating and the adhesor layer. In certain embodiments, the coating can be configured such that, when the coating is applied to the convex and the concave side of a polycarbonate ophthalmic lens, the luminous transmittance of the lens is greater than or equal to about 97.5%. The coating can be configured such that, when the coating is applied to at least the convex side of a polycarbonate ophthalmic lens, the Tumble Average Ratio of the convex side of the lens is greater than or equal to about 7.

Some embodiments provide an improved coating for an ophthalmic lens. The coating can include a hardening layer of silica having a thickness greater than or equal to about 150 nm; a first thin film layer of substantially fully oxidized high-index metal oxide adjacent to the hardening layer, the first thin film layer having a refractive index and a density indicative of deposition by ion beam assisted physical vapor deposition; a second thin film layer of low-index material adjacent to the first thin film layer, the second thin film layer having a refractive index lower than the refractive index of the first thin film layer and a density lower than the density of the first thin film layer; a third thin film layer of substantially fully oxidized high-index metal oxide adjacent to the second thin film layer, the third film layer having a refractive index and a density indicative of deposition by ion beam assisted physical vapor deposition; and a fourth thin film layer of low-index material adjacent to the third thin film layer, the fourth thin film layer having a refractive index lower than the refractive index of the third thin film layer and a density lower than the density of the third thin film layer.

The coating can include an adhesor layer of material configured to adhere the hardening layer to a surface of the ophthalmic lens. The material of the adhesor layer can include at least one of Cr, SiO, Al₂Oₓ, or Al. The thicknesses of the first thin film layer, the second thin film layer, the third thin film layer, and the fourth thin film layer can be selected such that the thin film layers collectively form at least a portion of an antireflection interference coating. In certain embodiments, the thickness of the hardening layer is greater than or equal to about 300 nm.

Some embodiments provide stress balanced ophthalmic lens coatings. Coating layers that are under inherent compressive stress can be called “negatively stressed,” and layers that are under inherent tensile stress can be called “positively stressed.” In certain embodiments, a physical vapor deposition process for forming a coating on a substrate of an ophthalmic lens in a vacuum deposition chamber can include depositing a first plurality of thin film layers on the substrate, each of the first plurality of thin film layers being inherently negatively stressed. The process can include depositing a second plurality of thin film layers on the substrate, the second plurality of thin film layers having an increased level of inherent stress compared to the first plurality of thin film layers. Each of the second plurality of layers can be deposited by contacting the substrate with a vapor phase pulse of a metal source chemical and, simultaneously while contacting the substrate with the vapor phase pulse of a metal source chemical, contacting the substrate with an energetic ion beam. The energy level of the energetic ion beam can be selected such that inherent stresses in the second plurality of thin film layers are tuned to provide the increased level of inherent stress. As a result, the inherent stresses in the second plurality of thin film layers can at least partially balance the inherent stresses in the first plurality of thin film layers.

Thin film layers that are at least partially balanced can include, for example, first and second layers disposed adjacent to one another, where one layer is inherently negatively stressed and the other layer is inherently positively stressed.

In some embodiments, the metal source chemical can include at least one metal selected from the group consisting of titanium (Ti), zirconium (Zr), hafnium (Hf), vanadium (V), niobium (Nb), tantalum (Ta), chromium (Cr), and cerium (Ce). In certain embodiments, the metal source chemical can be a metal halide, a metal oxide, or a metal organic compound.

In some embodiments, the energetic ion beam can be generated by an End Hall ion source. The energetic ion beam can be generated in the vacuum deposition chamber or can be generated remotely from the vacuum deposition chamber and directed into the vacuum deposition chamber.

The first plurality of thin film layers and the second plurality of thin film layers can form at least a portion of a multilayer interference coating. Each of the first plurality of thin film layers can be disposed in alternating relationship with each of the second plurality of thin film layers.

The process can include adjusting the energy level of the energetic ion beam during deposition of one or more of the second plurality of thin film layers such that inherent stress at an upper interface of the one or more of the second plurality of thin film layers at least partially balances inherent stress in a layer adjacent to the upper interface. The process can also include adjusting the energy level of the energetic ion beam during deposition of the one or more of the second plurality of thin film layers such that inherent stress at a lower interface of the one or more of the second plurality of thin film layers at least partially balances inherent stress in a layer adjacent to the lower interface.

In certain embodiments, depositing the first plurality of thin film layers on the substrate includes, for at least one of the first plurality of thin film layers, contacting the substrate with a vapor phase pulse of silica and, simultaneously while contacting the substrate with the vapor phase pulse of silica, contacting the substrate with an energetic ion beam. The energy level of the energetic ion beam can be selected such that inherent stresses in the at least one of the first plurality of thin film layers is tuned to at least partially balance inherent stresses in the second plurality of thin film layers.

Contacting the substrate with an energetic ion beam can include directing ionized species of one or more process gasses towards the substrate. In some embodiments, the one or more process gasses can include an inert gas, oxygen, or a combination of oxygen and an inert gas. The one or more process gasses can include argon, xenon, krypton, neon, another inert gas, or a combination of inert gases.

Some embodiments provide a coating for an ophthalmic lens. The coating can include a hardening layer of silica having a thickness greater than or equal to about 150 nm and at least one thin film layer of metal oxide. A level of inherent stress of the at least one thin film layer can be tuned by depositing the at least one thin film layer using ion beam assisted deposition. The coating can include at least one inherently compressively stressed thin film layer. The magnitude of stress in the at least one thin film layer can be tuned during deposition of the at least one thin film layer to at least partially balance the inherent stresses in the hardening layer and in the at least one inherently compressively stressed thin film layer.

The coating can include an adhesor layer of material configured to adhere the hardening layer to a surface of the ophthalmic lens. The material of the adhesor layer can include at least one of Cr, SiO, Al₂Oₓ, or Al. The at least one thin film layer and the at least one inherently compressively stressed thin film layer can form at least a portion of a multilayer interference coating. The thickness of the hardening layer can be about 300 nm.

Some embodiments provide an abrasion resistant ophthalmic lens coating. For example, a physical vapor deposition process for forming a coating on a substrate of a plastic ophthalmic lens in a vacuum deposition chamber can include positioning the plastic ophthalmic lens such that at least one surface of the plastic ophthalmic lens is exposed to the vacuum deposition chamber and depositing a hardening layer of silica on the substrate. The hardening layer can have a thickness greater than or equal to about 150 nm. The process can include depositing a multilayer interference stack on the substrate. In certain embodiments, the Tumble Average Ratio of a convex surface of a plastic ophthalmic lens with the coating formed thereon, as determined by subjecting the coated plastic ophthalmic lens to the Tumble Abrasion Test, is greater than or equal to about 7.

The thickness of the hardening layer can be greater than or equal to about 250 nm or about 300 nm. The coating can have a total thickness of less than or equal to about 650 nm or less than or equal to about 600 nm. In certain embodiments, the mean Tumble Average Ratio of the convex surface of the plastic ophthalmic lens with the coating formed thereon, as determined by subjecting five batches of the coated plastic ophthalmic lens to the Tumble Abrasion Test, is greater than or equal to about 9. In some embodiments, the plastic ophthalmic lens can be a polycarbonate ophthalmic lens or another suitable variety of plastic lens.

The process can include depositing an adhesor layer between the hardening layer and the plastic ophthalmic lens. The process can also include depositing a topcoat above the multilayer interference stack. Ion beam assisted deposition can be used to tune inherent stresses in one or more layers of the coating. For example, ion beam assisted deposition can be used to vary the inherent stresses in one or more thin film layers of the coating, thereby at least partially balancing the inherent stresses in the one or more thin film layers with inherent stresses in one or more inherently compressively stressed layers of the coating.

Some embodiments provide a coated plastic ophthalmic lens having a plastic lens element and a coating deposited on at least a convex surface of the plastic lens element. The coating can include a hardening layer of silica having a thickness greater than or equal to about 150 nm and a multilayer interference stack. In certain embodiments, the Tumble Average Ratio of the convex surface, as determined by subjecting the coated plastic ophthalmic lens to the Tumble Abrasion Test, is greater than or equal to about 7.

The coating can include an adhesor layer of material configured to adhere the hardening layer to a surface of the plastic lens element. The material of the adhesor layer can include at least one of Cr, SiO, Al₂Oₓ, or Al. The number of high-index layers and low-index layers in the multilayer interference stack can be less than or equal to six. The thickness of the hardening layer can be greater than or equal to about 300 nm.

Some embodiments provide a physical vapor deposition process for forming a coating on a substrate of an ophthalmic lens in a vacuum deposition chamber. For example, the process can include depositing a multilayer interference stack having a plurality of low refractive index layers and a plurality of high refractive index layers on the substrate by: depositing one or more of the plurality of high refractive index layers by contacting the substrate with a vapor phase pulse of one or more high refractive index source chemicals simultaneously while contacting the substrate with an energetic ion beam generated by an RF ion source; and depositing each of the plurality of low refractive index layers by contacting the substrate with a vapor phase pulse of one or more low refractive index source chemicals. At least one of the deposited plurality of low refractive index layers can be disposed adjacent to at least one of the deposited plurality of high refractive index layers. Thicknesses of the plurality of high refractive index layers and the plurality of low refractive index layers can be selected such that, when the multilayer interference stack is deposited on a surface of an ophthalmic lens, the luminous reflectance at the surface of the ophthalmic lens is less than or equal to about 2% using CIE illuminant D₆₅.

The process can include depositing a hardening layer comprising a first thickness of low index material on the substrate, wherein the hardening layer is disposed between the multilayer interference stack and the ophthalmic lens. The first thickness can be greater than or equal to about 150 nm. The process can include depositing at least a portion of the hardening layer by contacting the substrate with a vapor phase pulse of one or more low refractive index source chemicals simultaneously while contacting the substrate with an energetic ion beam generated by the RF ion source. Contacting the substrate with an energetic ion beam can include directing one or more ionized species of gas towards the substrate.

The one or more low refractive index source chemicals can include a material having a visible light refractive index less than or equal to about 1.5. Suitable low refractive index source chemicals include silica or a mixture of silica and aluminum oxide. In some embodiments, the one or more high refractive index source chemicals can include one of zirconium oxide, niobium oxide, titanium oxide, tantalum oxide, cerium oxide, hafnium oxide, indium oxide doped with tin oxide, zinc oxide doped with aluminum oxide, or a mixture of zirconium oxide and tantalum oxide.

The plurality of high refractive index layers can include a plurality of adjacent thin film layers. The plurality of adjacent thin film layers can include at least one layer that reduces or eliminates static charge buildup on the ophthalmic lens. The at least one layer that reduces or eliminates static charge buildup can include indium oxide doped with tin oxide, zinc oxide doped with aluminum oxide, another suitable transparent conductive oxide, or a combination of materials.

The process can include depositing an adhesor layer configured to adhere the coating to the substrate. The coating can be configured such that, when the coating is applied to the convex side and the concave side of a polycarbonate ophthalmic lens, the luminous transmittance of the lens is greater than or equal to about 97.5% using CIE illuminant D₆₅.

Certain embodiments provide an ophthalmic lens coating formed by one or more of the processes disclosed herein. Some embodiments provide an ophthalmic lens having a coating formed by one or more of the processes disclosed herein. Certain embodiments provide eyewear incorporating at least one ophthalmic lens having a coating formed by one or more processes disclosed herein.

In some embodiments, a coating for an ophthalmic lens includes a hardening layer disposed on a substrate of the ophthalmic lens including a low index material having a thickness greater than or equal to about 150 nm and a multilayer interference stack disposed over the hardening layer. The multilayer interference stack can include a plurality of high refractive index layers. At least one of the plurality of high refractive index layers can include a thin film having a substantial density gradient through at least a portion of the thickness of the thin film. Each of the plurality of high refractive index layers can be deposited by contacting the substrate with a vapor phase pulse of one or more high refractive index source chemicals simultaneously while contacting the substrate with an energetic ion beam generated by an ion source. The multilayer interference stack can include a plurality of low refractive index layers deposited by contacting the substrate with a vapor phase pulse of one or more low refractive index source chemicals. At least one of the plurality of low refractive index layers can be disposed adjacent to at least one of the plurality of high refractive index layers. Thicknesses of the plurality of high refractive index layers and the plurality of low refractive index layers can be selected such that, when the multilayer interference stack is deposited on a surface of an ophthalmic lens, the luminous reflectance at the surface of the ophthalmic lens is less than or equal to about 2% using CIE illuminant D₆₅.

In certain embodiments, at least one of the plurality of high refractive index layers comprises a thin film having a substantial stress gradient through at least a portion of the thickness of the thin film. In some embodiments, the coating can include an adhesor layer of material configured to adhere the hardening layer to the ophthalmic lens. The material of the adhesor layer can include at least one of Cr, SiO, Al₂Oₓ, or Al.

At least one of the plurality of high refractive index layers can include a layer configured to reduce or prevent accumulation of static charge on the ophthalmic lens. The coating can include a topcoat layer disposed over the multilayer interference stack. The topcoat layer can be constructed from a hydrophobic material.

Certain embodiments provide another physical vapor deposition process for forming a coating on a substrate of an ophthalmic lens in a vacuum deposition chamber. For example, the process can include depositing a multilayer interference stack having a plurality of low refractive index layers and a plurality of high refractive index layers on the substrate by: depositing one or more of the plurality of high refractive index layers by contacting the substrate with a vapor phase pulse of niobium source chemical simultaneously while contacting the substrate with an energetic ion beam generated by an RF ion source; and depositing each of the plurality of low refractive index layers by contacting the substrate with a vapor phase pulse of one or more low refractive index source chemicals. At least one of the plurality of low refractive index layers can be disposed adjacent to at least one of the plurality of high refractive index layers. The one or more of the plurality of high refractive index layers can include a layer of substantially stoichiometric Nb₂O₅.

The process can include depositing at least one of the plurality of high refractive index layers by contacting the substrate with a metal source chemical comprising at least one metal selected from the group consisting of titanium (Ti), zirconium (Zr), hafnium (Hf), vanadium (V), tantalum (Ta), chromium (Cr), and cerium (Ce). The niobium source chemical can be selected from the group consisting of niobium halides, niobium oxides, and niobium organic compounds.

An ion energy level of the energetic ion beam can be adjusted during deposition of one or more of the high refractive index layers. The energetic ion beam can be generated in the vacuum deposition chamber or be generated remotely from the vacuum deposition chamber and directed into the vacuum deposition chamber.

The plurality of high refractive index layers can include two or more layers disposed immediately adjacent to one another. The plurality of high refractive index layers can include a layer comprising indium oxide doped with tin oxide, zinc oxide doped with aluminum oxide another suitable transparent conductive oxide, or a combination of materials.

The process can include depositing a hardening layer of low refractive index material having a thickness greater than or equal to 150 nm between the multilayer interference stack and the substrate. The process of depositing the hardening layer can include contacting the substrate with a vapor phase pulse of one or more low refractive index source chemicals and simultaneously while contacting the substrate with the vapor phase pulse of one or more low refractive index source chemicals, contacting the substrate with an energetic ion beam generated by the RF ion source. The process can include adjusting the energy level of the energetic ion beam during deposition of the hardening layer such that inherent stress at an upper interface of the hardening layer at least partially balances inherent stress in a layer adjacent to the upper interface

Contacting the substrate with an energetic ion beam can include directing ionized species of one or more process gasses towards the substrate. The one or more process gasses can include an inert gas, oxygen, or a combination of oxygen and an inert gas. The process can include cleaning the substrate before depositing the coating by contacting the substrate with ionized species of an inert gas, a reactive gas, or a mixture inert gas and reactive gas.

In some embodiments, a coating for an ophthalmic lens includes a multilayer interference stack disposed on a substrate of the ophthalmic lens. The multilayer interference stack can include a plurality of high refractive index layers comprising one or more layers of substantially stoichiometric Nb₂O₅ and a plurality of low refractive index layers deposited by contacting the substrate with a vapor phase pulse of one or more low refractive index source chemicals, wherein at least one of the plurality of low refractive index layers is disposed adjacent to at least one of the plurality of high refractive index layers.

The coating can include a hardening layer of low refractive index material having a thickness greater than or equal to 150 nm, the hardening layer disposed between the multilayer interference stack and the ophthalmic lens. The coating can include an adhesor layer of material configured to adhere the hardening layer to a surface of the ophthalmic lens. The adhesor layer can include at least one of Cr, SiO, Al₂Oₓ, or Al.

The inherent stresses in the one or more layers of substantially stoichiometric Nb₂O₅ can be tuned using an RF ion source to at least partially balance the inherent stresses in adjacent layers of the coating.

The plurality of high refractive index layers can include one or more layers having a material system comprising a mixture of zirconium oxide and tantalum oxide. The thicknesses of the plurality of high refractive index layers and the plurality of low refractive index layers can be selected such that, when the multilayer interference stack is deposited on a surface of an ophthalmic lens, the luminous reflectance at the surface of the ophthalmic lens is less than or equal to about 2% using CIE illuminant D₆₅.

### BRIEF DESCRIPTION OF THE DRAWINGS

The embodiments depicted in the accompanying drawings are for illustrative purposes and should in no way be interpreted as limiting the scope of the inventions. In addition, various features of different disclosed embodiments can be combined to form additional embodiments, which are part of this disclosure. Any feature or structure can be removed or omitted.

FIG. 1A is a perspective view of eyewear (e.g., a pair of spectacles) incorporating lenses with at least one lens coating in accordance with some embodiments.

FIG. 1B is a cross-sectional view of a lens with a convex surface coating in accordance with certain embodiments.

FIG. 1C is a cross-sectional view of a lens with convex and concave surface coatings in accordance with some embodiments.

FIG. 2 is a schematic diagram of a multi-layer ophthalmic lens coating in accordance with certain embodiments.

FIG. 3 is a schematic diagram of another multi-layer ophthalmic lens coating in accordance with some embodiments.

### DETAILED DESCRIPTION OF PREFERRED EMBODIMENTS

Although certain preferred embodiments and examples are disclosed below, inventive subject matter extends beyond the specifically disclosed embodiments to other alternative embodiments and/or uses, and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence.

Various operations may be described as multiple discrete operations in turn, in a manner that may be helpful in understanding certain embodiments; however, the order of description should not be construed to imply that these operations are order dependent. Additionally, the structures described herein may be embodied as integrated components or as separate components.

For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein.

An antireflective coating for a lens can have a number of different configurations. For example, an interference coating can have one or more thin layers that are configured to reduce reflections through destructive interference. In some configurations, an antireflective interference coating has multiple layers formed from alternating low-refractive index and high-refractive index materials. A low-refractive index material such as silicon dioxide can be used to form one or more low-index layers. High-refractive index materials include metal oxides such as zirconium dioxide, tantalum pentoxide, and titanium dioxide, which can be used to form one or more high-index layers.

Some ARCs have low transmission, adhesion, and/or abrasion resistance characteristics. For example, in some optical elements with a synthetic resin, the heating temperature in vapor deposition can be limited by the low melting point of the substrate. Because of this limitation, the density of the layers formed in antireflection layers may be lower than the optimal density, and the film refractivity and abrasion resistance of the film may suffer.

A polymeric optical element, such as a lens for eyewear, can include an organic hard coat film formed on the plastic lens substrate for improving the scratch resistance of the coated lens. An inorganic antireflection film can be formed on top of the hard coat film. This AR coating method addresses mainly abrasion resistance and possibly adhesion. In some embodiments, a highly abrasion resistant lacquer disposed between the ARC and the substrate may not address all drawbacks of existing coating technologies.

An ophthalmic lens can also have a hardening layer (for example, SiO₂) of increased thickness in the AR stack. However, in some embodiments, an increased thickness hardening layer, without other improvements, can induce further adhesion problems while increasing the abrasion resistance minimally. An increased thickness hardening layer may not improve the transmission of the lens.

In some embodiments, coating processes are configured to maintain high transmission while improving abrasion resistance and adhesion of the coating to a finished lens. Coating processes can include one or more features, which, in some cases, can be combined with other disclosed features to provide further advantages.

Coating processes can be used to form an ARC on one or both sides of an ophthalmic lens. In some embodiments, the ARC includes an increased thickness hardening layer. The hardening layer can be formed using physical vapor deposition with a suitable vapor source such as, for example, SiO₂. The thickness of the hardening layer can be greater than or equal to about 150 nm, greater than or equal to about 250 nm, between about 150 nm and about 300 nm, between about 250 nm and 350 nm, about 300 nm, or another suitable thickness. The hardening layer can be deposited at a rate that allows the layer to form with substantial uniformity and high density.

The term “ophthalmic lens” is used herein in its broad and ordinary sense. For example, ophthalmic lenses encompass corrective lenses, non-corrective lenses, tinted lenses, sunglass lenses, plastic lenses, glass lenses, and other lenses used in eyewear. The techniques and equipment used to make ophthalmic lenses has typically differed from the techniques and equipment used to make other types of lenses, including lenses used in precision optical systems.

The term “physical vapor deposition” is used herein in its broad and ordinary sense. For example, the term encompasses coating techniques that involve physical processes in which a film is deposited by vacuum deposition on a surface. The term also encompasses coating techniques where a chemical or mechanical change in the coating material is induced by a directed energy source, such as an ion beam. For example, in some embodiments, the deposition surface may be activated chemically by exposure to ionized gases or reactive gases before or during physical vapor deposition. The term “physical vapor deposition” does not generally encompass chemical vapor deposition techniques as understood by one of ordinary skill in the art. For example, the term does not encompass a deposition technique wherein the deposition occurs principally by introducing a gas stream containing precursor gases outside of a plasma ion source and into the plasma ion beam. In physical vapor deposition, the material to be deposited is typically introduced into the deposition chamber in its solid phase and vaporized.

An antireflective coating or stack can include a variety of materials, including materials that are partially, mostly, nearly entirely, or entirely transparent to visible light. In some embodiments, the material system of an antireflective stack is free or mostly free of materials that absorb any substantial portion of visible light. In certain embodiments, the luminous transmittance of a clear polycarbonate lens coated with an antireflective stack described herein is greater than or equal to about 97%, greater than or equal to about 97.5%, about 98%, or greater than or equal to about 98%. In some embodiments, the luminous reflectance of the coated lens is less than about 4%, less than about 3%, less than about 2.5%, or less than about 2%. The disclosed coatings can be applied to the convex surface, the concave surface, or both the convex and concave surfaces of a lens. In certain embodiments, the luminous reflectance of a coated surface of a lens is less than about 2%, less than about 1.5%, less than about 1%, or less than about 0.5%. As used herein, luminous transmittance and luminous reflectance can be measured with respect to a standard daylight illuminant, such as CIE illuminant D₆₅.

In some embodiments, ion beam assisted deposition (IBAD) is used during deposition of one or more layers of the antireflective stack. The term “ion beam assisted deposition” is used in its ordinary sense. For example, IBAD encompasses thin film deposition processes in which a substrate is exposed to a vapor phase coating material in a vacuum chamber. Any suitable vacuum chamber can be used, including, for example, the SatisLoh 1200 Box coater available from SatisLoh AG of Baar, Switzerland. During IBAD, individual coating atoms or molecules can condense on the substrate to form a coating. Simultaneously, an energetic ion beam is directed at the substrate during deposition of the coating material. In some embodiments, a different ion beam power is selected for different layers of the coating, and the ion beam can be deactivated entirely during deposition of one or more layers. In certain embodiments, the ion beam power is changed during deposition of a single layer.

The ion beam can be generated by an ion source. Any ion source suitable for assisted deposition on an ophthalmic lens substrate can be used. Examples of such ion sources include an End Hall ion source, a Radio Frequency (RF) ion source, and an Anode Layer Source (ALS). The Mark II and Mark II⁺ Ion Sources, made by Veeco Instruments Inc. of Woodbury, N.Y., are examples of suitable End Hall ion sources. A suitable process gas can be used with the ion source. Process gasses can include inert gasses (e.g., argon, xenon, krypton, or neon), oxygen, reactive gasses, carbon-bearing gasses, other gasses, and combinations of gasses.

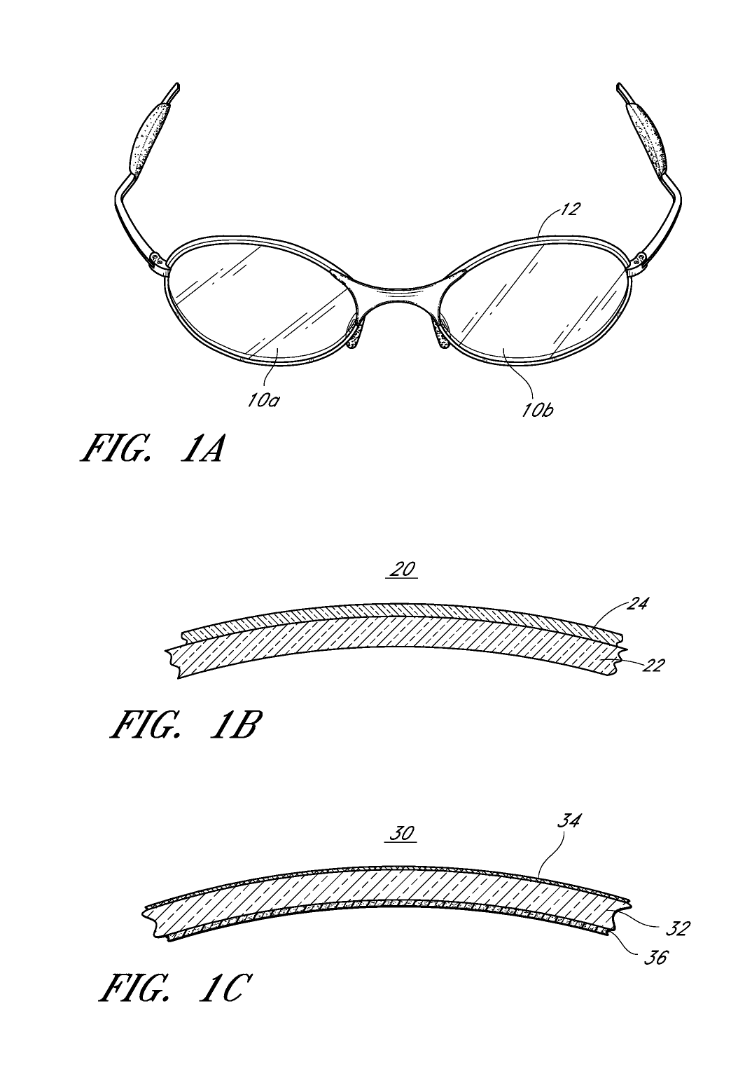

In the embodiment illustrated in FIG. 1A, a pair of spectacles includes ophthalmic lenses 10a, 10b having at least one lens coating The lenses 10a, 10b are connected to a frame 12 that can have any suitable configuration. The spectacles can be of any type, including general-purpose eyewear, special-purpose eyewear, sunglasses, driving glasses, sporting glasses, indoor eyewear, outdoor eyewear, vision-correcting eyewear, contrast-enhancing eyewear, eyewear designed for another purpose, or eyewear designed for a combination of purposes.

FIG. 1B shows an embodiment of an ophthalmic lens 20 in which an ophthalmic lens coating 24 is disposed on a convex surface of the lens body substrate 22. The thickness of the coating 24 is exaggerated in the drawings, and it is understood that the coating 24 can be much thinner than the lens body 22. The coating 24 can include one or more functional layer groups as described herein.

FIG. 1C shows an embodiment of an ophthalmic lens 30 in which an ophthalmic lens coating 34 is disposed on a convex surface of the lens body substrate 32 and another ophthalmic lens coating 36 is disposed on a concave surface of the lens body substrate 32. The relative thicknesses of the lens elements shown in FIG. 1C are not drawn to scale, and it is understood that each of the lens elements can have any suitable thickness. In some embodiments, each of the coatings 34, 36 can include one or more functional layer groups as described herein. Further, the coatings 34, 36 can have substantially the same composition or substantially different compositions. The configurations of each of the coatings 34, 36 can be selected to achieve any desired purpose or purposes, and a wide variety of possible configurations exist.

A lens can be coated with one or more functional layer groups. Each functional layer group can include one or more layers, where “layer” is used in its broad and ordinary sense. For example, a layer can be a substantially contiguous film deposited from a single coating material or a single group of coating materials. In some embodiments, each layer has a substantially uniform composition, although it is understood that variations in microstructure or morphology may occur within a layer. The functional layer groups can include, for example, a multilayer AR stack, a hardening layer, a topcoat layer, a hydrophobic layer, an anti-static layer, an adhesor layer, another functional layer, or a combination of layers. The AR stack can include a plurality of high-index layers and a plurality of low-index layers. Low refractive index layers are made from materials that typically have a refractive index of less than about 1.5 in the visible spectrum, while high refractive index layers are selected from materials with a refractive index greater than the refractive index of at least one of the low-index materials used in the AR stack.

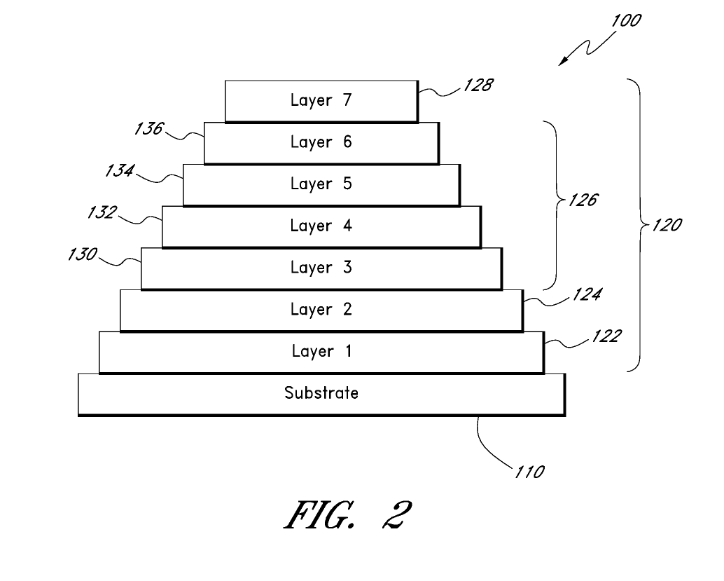

FIG. 2 shows a schematic diagram of the layers of an example coated ophthalmic lens 100. The diagram shows the order of the coating layers 120 and substrate 110 but does not indicate the thicknesses of the layers and substrate, which are not drawn to scale. The substrate 110 can be made from any suitable ophthalmic lens material such as, for example, polycarbonate, acrylic, resin, glass, another material, or a combination of materials. The substrate 110 can include one or more lens elements or other structures. The substrate 110 can also be hardcoated and/or have other surface treatments.

In the embodiment illustrated in FIG. 2, the coating 120 includes four functional layer groups 122, 124, 126, 128. The first functional layer group is an adhesor layer 122 that is disposed on the substrate. The adhesor layer 122 can be made from a material system that can adhere the substrate 110 to the coating 120. The material system for the adhesor layer 122 can include Cr, SiO, Al₂Oₓ, Al, another suitable material, or a combination of materials. The thickness of the adhesor layer is generally greater than or equal to about 0.1 nm and/or less than or equal to about 10 nm. In some embodiments, the adhesor layer 122 material is a mixture of Cr and SiO, and the thickness of the layer 122 is between about 0.6 nm and about 1 nm. The adhesor layer 122 can be deposited without using IBAD. Before the adhesor layer 122 is deposited, the substrate can be cleaned by providing a pulse of inert or reactive process gas to the deposition chamber with the ion source activated at low energy. Many other variations or alternative configurations for the adhesor layer 122 are possible.

In the embodiment illustrated in FIG. 2, a hardening layer 124 is disposed on the adhesor layer 122. The hardening layer 124 can be an amorphous layer of silica with a thickness substantially greater than the other layers of the coating 120. In some embodiments, the hardening layer 124 includes a film of SiO₂ between about 150 nm and about 300 nm thick. In certain embodiments, the thickness of the hardening layer is about 300 nm. Other configurations and thicknesses of the hardening layer 124 are possible.

The hardening layer 124 can be deposited using IBAD, although some coatings have a hardening layer 124 that is deposited without using IBAD. The use of IBAD during deposition of the hardening layer 124 is generally more preferred when the energy of the ion beam is relatively tunable and generally less preferred when the ion beam energy is less tunable or exhibits greater variability. For example, in some embodiments that use an End Hall source as the ion source, the hardening layer 124 is deposited without using IBAD.

An antireflective (AR) stack 126 is disposed on the hardening layer 124. The AR stack 126 includes two high-index layers 130, 134 and two low-index layers 132, 136. The high-index layers 130, 134 can be formed from a high-index material such as, for example, ZrO₂. The low-index layers 132, 136 can be formed from a low-index material such as, for example, SiO₂. The thicknesses of the layers 130, 132, 134, 136 can be selected to achieve maximum destructive interference of visible light reflected at the interfaces between the layers, thereby increasing visible light transmission.

In some embodiments, IBAD is used during deposition of only the high-index layers 130, 134 in the stack 126. In at least some such embodiments, the stresses between high-index layers 130, 134 and low-index layers 132, 136 can be at least partially balanced than if IBAD were not used at all or if IBAD were used during deposition of both the high-index layers 130, 134 and the low-index layers 132, 136. High-index layers of an AR stack can be compacted by IBAD, which makes the microstructure of the layers more crystalline and increases the hardness of the layers. IBAD can also increase the oxidation of the high-index layers, which results in greater transparency.

Thin film layers that are at least partially balanced can include, for example, first and second layers disposed adjacent to one another, where one layer is inherently negatively stressed and the other layer is inherently positively stressed. In certain embodiments, the first layer can have a level of inherent positive stress that substantially balances or at least partially balances the level of inherent negative stress in the compressively stressed layer. In some embodiments, when the stresses of two or more layers that are at least partially balanced are summed, the magnitude of the result is less than the magnitude of the highest level of stress in any of the two or more layers alone. In certain embodiments, when the stresses of two or more layers that are substantially balanced or at least partially balanced are summed, the magnitude of the result is close to zero or substantially equal to zero. In other embodiments, when the stresses of two or more layers that are at least partially balanced are summed, the magnitude of the result is not close to zero or substantially equal to zero.

The inherent stress in one or more layers of the coating shown in FIG. 2 can be varied using IBAD. In some embodiments, the energy level of the ion beam during IBAD can be selected to tune the inherent stress of a layer to better balance the stresses between the layer and adjacent layers. For example, IBAD can be used during deposition of a high-index ZrO₂ layer between compressively stressed, low-index SiO₂ layers. In this example, the ion energy during deposition of the ZrO₂ layer can be selected to be about 100 eV when the layer is deposited at a rate of about 0.6 nm/s and when Argon is used as the process gas. The ZrO₂ layer can have an increased level of inherent stress compared to the low-index layers, resulting in a low level of overall stress in the stack and reduced local stresses at the upper and/or lower interfaces. In some embodiments, the ZrO₂ layer can have a level of inherent positive stress that substantially balances or at least partially balances the level of inherent negative stress in the compressively stressed SiO₂ layers. In certain embodiments, only the high-index layers of a multilayer interference coating are deposited using IBAD. In certain such embodiments, all of the high-index layers are deposited using IBAD.

In the embodiment illustrated in FIG. 2, a topcoat layer 128 is disposed on the AR stack 126. The topcoat layer 128 can include a material system configured to impart one or more properties to the surface of the finished lens. For example, the material system of the topcoat layer 128 can include a hydrophobic material. The thickness of the topcoat layer 128 is typically between about 3 nm and about 25 nm, although the thickness of the layer can depend largely on the material system of the layer. The topcoat layer 128 is typically deposited without using IBAD, although IBAD made be used during deposition of the topcoat layer 128 in certain embodiments. Many configurations for the topcoat layer 128 are possible.

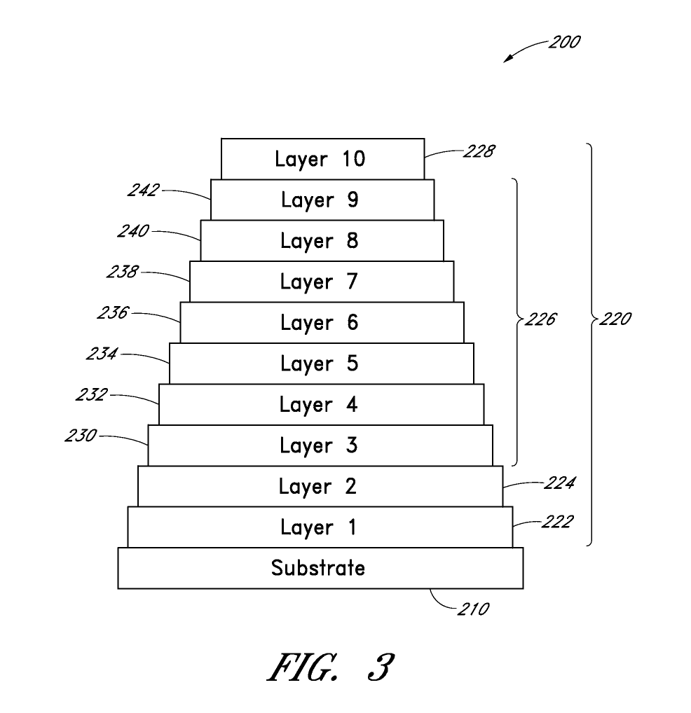

FIG. 3 shows a schematic diagram of the layers of another example coated ophthalmic lens 200. The diagram shows the order of the coating layers 220 and substrate 210 but does not indicate the thicknesses of the layers and substrate, which are not drawn to scale. The substrate 210 can be made from any suitable ophthalmic lens material such as, for example, polycarbonate, acrylic, resin, glass, another material, or a combination of materials. The substrate 210 can include one or more lens elements or other structures. The substrate 210 can also be hardcoated and/or have other surface treatments.

In the embodiment illustrated in FIG. 3, the coating 220 includes four functional layer groups 222, 224, 226, 228. The first functional layer group is an adhesor layer 222 that is disposed on the substrate. The adhesor layer 222 can be made from a material system that can adhere the substrate 210 to the coating 220. The material system for the adhesor layer 222 can include Cr, SiO, Al₂Oₓ, Al, another suitable material, or a combination of materials. The thickness of the adhesor layer is generally greater than or equal to about 0.1 nm and less than or equal to about 10 nm. In some embodiments, the adhesor layer 222 material is a mixture of Cr and SiO, and the thickness of the layer 222 is between about 0.6 nm and about 1 nm. The adhesor layer 222 can be deposited without using IBAD. Before the adhesor layer 222 is deposited, the substrate can be cleaned by providing a pulse of inert process gas to the deposition chamber with the ion source activated at low energy. Many other variations or alternative configurations for the adhesor layer 222 are possible.

A hardening layer 224 is disposed on the adhesor layer 222. The hardening layer 224 can be an amorphous layer of silica with a thickness substantially greater than the other layers of the coating 220. In some embodiments, the hardening layer 224 includes a film of SiO₂ between about 150 nm and about 300 nm thick. In certain embodiments, the thickness of the hardening layer 224 is about 300 nm. Other configurations and thicknesses of the hardening layer 224 are possible.

The hardening layer 224 can be deposited using IBAD, although some embodiments include coatings having a hardening layer 224 that is deposited without using IBAD. The use of IBAD during deposition of the hardening layer 224 is generally more preferred when the energy of the ion beam is relatively tunable and generally less preferred when the ion beam energy is less tunable or exhibits greater variability. For example, in some embodiments that use an End Hall source as the ion source, the hardening layer 224 is deposited without using IBAD. In some embodiments that use a tunable ion source, such as an RF source, the hardening layer 224 is deposited using IBAD. The ion energy used can be varied as deposition of the hardening layer 224 progresses from the lower interface to the upper interface. By varying ion energy during deposition, the inherent stresses within the layer 224 can be tailored to at least partially balance stresses in adjacent layers 222, 230. In some embodiments, the ion energy used increases as deposition proceeds from the lower interface towards the upper interface of the layer 224. The variation in ion energy can be gradual or can occur in one or more steps. The ion source can also be completely off during at least a portion of the layer deposition.

Some types of ion sources exhibit greater variability in the energy of generated ions that other types of ion sources. An example of an ion source that generates ions with relatively high energetic variability is an End Hall source. The energetic variability of ions produced by an End Hall source can be substantially higher, e.g., about 8 times higher (or about an order of magnitude higher) than the energetic variability of ions produced by an RF ion source. In other words, the energy of individual ions emitted by an End Hall source can vary substantially from the average ion energy level. Thus, the tunability and/or selectivity of an ion source may be less than desired. Further, use of an End Hall ion source with certain process materials, including silica, may degrade the performance or condition of the ion source. In some embodiments, using an RF ion source can mitigate or eliminate some of the drawbacks associated with ion sources with high energetic variability in general and with End Hall ion sources in particular.

An antireflective (AR) stack 226 is disposed on the hardening layer 224. The AR stack 226 includes a layer system with low- and high-index layers. In the embodiment shown in FIG. 3, the stack 226 includes multiple (e.g., two) high-index material regions and two low-index material regions. The first high-index region is a single layer 230 of high-index material. The second high-index region includes more layers than the first high-index region (e.g., four layers 234, 236, 238, 240) having distinct compositions of high-index material. The high-index regions alternate with two single-layer low-index regions 232, 242. The high-index layers 230, 234, 238, 240 can be formed from a high-index material such as, for example, ZrO₂, Ta₂O₅, a mixture of zirconium oxide and tantalum oxide, indium oxide, indium oxide doped with tin oxide (ITO), zinc oxide, zinc oxide doped with aluminum oxide (AZO), Nb₂O₅, a blended material, another material, or a combination of materials. The layer materials within a high-index region can be selected to improve the transmission, anti-static characteristics, and/or other properties of the coating 220. The low-index layers 232, 242 can be formed from a low-index material such as, for example, SiO₂, a mixture of SiO₂ and Al₂O₃, a blended material, another suitable material, or a combination of materials. The thicknesses of the layers 230, 232, 234, 236, 238, 240, 242 can be selected to achieve high destructive interference of visible light reflected at the interfaces between the layers, thereby increasing visible light transmission.

In some embodiments, IBAD is used during deposition of only the layers 230, 234, 236, 238, 240 of the stack 226 made from high-index materials. In certain embodiments, the stresses between layers can be at least partially unbalanced if IBAD is not used at all or if IBAD is used during deposition of both the high-index layers 230, 234, 236, 238, 240 and the low-index layers 232, 242. High-index layers of an AR stack can be compacted by IBAD, which makes the microstructure of the layers more crystalline and increases the hardness of the layers. IBAD can also increase the oxidation of the high-index layers, which results in greater transparency. By using a tunable ion source capable of providing high ion energy levels, such as an RF source, the composition stoichiometry of the film layers can be controlled with precision. Further, the density of the layers deposited with IBAD can be substantially increased.

IBAD can also be used to improve the balance of stresses between layers that have different levels of inherent stresses, thereby decreasing the stress in an overall stack. In a thin film layer deposited on a substrate, inherent stress can vary along a continuum extending from a tensile stressed state—where the layer is under tension, a stress state leading to expansion—to a compressively stressed state—where the layer is under compression. Thin films deposited without IBAD are typically compressively stressed at varying levels. As used herein, tensile stress will be called “positive stress,” while compressive stress will be called “negative stress.” When tuning of inherent stress in a layer is discussed herein, it is understood that an “increase” in inherent stress refers to a change in the direction of increasing positive (i.e., tensile) stress and decreasing negative (i.e., compressive) stress.

Overall stress in a coating can be approximated by summing the inherent stresses of the individual layers in the coating, while local stress at an interface between layers in the coating is at least partially influenced by the sum of the inherent stresses in the layers adjacent to the interface. Local stress can be reduced or eliminated when adjacent layers are generally balanced. As an example, two adjacent layers are generally balanced when the magnitude of positive stress in one layer is close to the magnitude of negative stress in the other layer.

The inherent stress in one or more thin film layers of the coating shown in FIG. 3 can be increased using IBAD. In some embodiments, the energy level of the ion beam during IBAD can be selected to tune the inherent stress of a layer to better balance the stresses between the layer and adjacent layers. For example, IBAD can be used during deposition of a high-index layer having a blended Zr—Ta-oxide composition that, in its final configuration, is disposed between compressively stressed, low-index layers comprising SiO₂. In this example, the ion energy during deposition of the high-index layer can be selected to be about 100-300 eV when the layer is deposited at a rate of about 0.3 nm/s and when oxygen or an argon-oxygen blend is used as the process gas. The resulting high-index layer will have an increased level of inherent stress compared to the same high-index layer deposited without ion beam assisted deposition, thereby lowering overall stress in the stack and reducing local stresses at the upper and/or lower interfaces. In some embodiments, a high-index layer deposited using IBAD can have a level of inherent positive stress that is substantially balanced or at least partially balanced with the level of inherent negative stress in the compressively stressed low-index layers. In certain embodiments, only the high-index layers of a multilayer interference stack are deposited using IBAD. In certain such embodiments, all of the high-index layers are deposited using IBAD.

A graduated IBAD technique can be used to vary the energy level of the ion beam during deposition of a single layer. When such a technique is used, the stress at the upper interface of the layer can at least partially balance the stress in the above adjacent layer and the stress at the lower interface of the layer can at least partially balance the stress in the below adjacent layer, even when the inherent stresses in the above adjacent and below adjacent layers are different. By varying the energy level of the ion beam within at least a portion of the range of energy levels at which an ion source can operate, a layer may be deposited such that a substantial inherent stress gradient exists within the deposited layer. In some embodiments, a graduated IBAD technique is used during deposition of one or more high index layers. In certain embodiments, the graduated IBAD technique is used during deposition of each of the high index layers. In some embodiments, the graduated IBAD technique is used during deposition of a hardening layer. Many other variations are possible, and it is understood that the graduated IBAD technique may be advantageously used during deposition of other layers of a lens coating.

The use of IBAD during deposition of a layer can also increase the density of the layer. The density of the layer can increase with higher ion beam energy levels through at least a portion of the range of energy levels that an ion source can produce. Some ion sources may have a greater range of possible energy levels than other ion sources. For example, a typical RF ion source has the capability of operating at higher ion beam energy levels than a typical End Hall source. By varying the energy level of the beam within at least a portion of the range of energy levels at which an ion source can operate, a layer may be deposited such that a substantial density gradient exists within the deposited layer.

In the embodiment illustrated in FIG. 3, a topcoat layer 228 is disposed on the AR stack 226. The topcoat layer 228 can include a material system configured to impart one or more properties to the surface of the finished lens. For example, the material system of the topcoat layer 228 can include a hydrophobic material. The thickness of the topcoat layer 228 is typically between about 3 nm and about 25 nm, although the thickness of the layer can depend largely on the material system of the layer. The topcoat layer 228 is typically deposited without using IBAD, although IBAD made be used during deposition of the topcoat layer 228 in certain embodiments. Many configurations and application methods for the topcoat layer 228 are possible.

### Example Coating Configurations

A first example coating configuration for a polycarbonate ophthalmic lens is shown in Table A. The structure of the example configuration is similar in many respects to the embodiment shown in FIG. 2, and the functional layer groups in the table are identified by corresponding reference numbers. Additional details regarding the layer materials, the thickness of each layer, the rate of deposit for each layer, whether IBAD is used during deposition of a layer, the ion energy of an End Hall ion source, and the process gas are provided in this example. The example also provides details for a clean step that can take place prior to deposition of the adhesor layer. During the clean step, the substrate can be contacted with ionized species of an inert gas, a reactive gas, or a mixture inert gas and reactive gas. In this example, the deposition process begins with the clean step and proceeds in order with deposition of the layers beginning with the adhesor layer 122 (nearest the ophthalmic lens) and ending with the topcoat layer 128 (furthest from the ophthalmic lens).

TABLE A

| Functional | Layer | Thickness | | Use | Ion energy |
|---|---|---|---|---|---|
| layer group | material | Rate of deposit | | IBAD? | Process gas |
| Topcoat 128 | Hydrophobic | 3 nm-25 nm | | No | N/A |
| | material | 0.2 | nm/s | | |
| | system | | | | |
| Antireflective | SiO₂ | 90 | nm | No | N/A |
| stack 126 | | 1.3 | nm/s | | |
| | ZrO₂ | 56 | nm | Yes | 100 eV |
| | | 0.6 | nm/s | | Argon |
| | SiO₂ | 32.67 | nm | No | N/A |
| | | 1.3 | nm/s | | |
| | ZrO₂ | 28 | nm | Yes | 100 eV |
| | | 0.6 | nm/s | | Argon |
| Hardening | SiO₂ | 300 | nm | No | N/A |
| layer 124 | | 1.3 | nm/s | | |
| Adhesor layer | Mixture of | 0.6-1.0 | nm | No | N/A |
| 122 | Cr and SiO | 0.02 | nm/s | | |

| | | | | |
|---|---|---|---|---|
| Clean step | N/A | N/A | No | 60 eV |
| | | | | Argon |

Certain advantages and features of the example coating configuration will now be discussed. The advantages that will be discussed are believed to be at least partially attributable to one or more aspects of the example coating configuration disclosed above. Some embodiments include these advantages. For example, the use of IBAD during the deposition of the high-index layers provides a very dense high-index material and also produces a very repeatable and controllable refractive index for the high-index layers. It has been observed that the abrasion resistance of a lens coated with the example coating configuration is substantially increased when compared to other coated ophthalmic lenses.

Among techniques for measuring abrasion resistance, an industry standard testing procedure known as the Tumble Abrasion Test, designed by Colts Laboratories of Clearwater, Fla., is particularly rigorous and applicable to the determination of the abrasion resistance of a coated lens. The Tumble Abrasion Test is described in a Tumble Abrasion Standard Operating Procedure document published by Colts Laboratories on Nov. 13, 2009. The document explains that a value known as the “Tumble Average Ratio” can be determined by performing a hazemeter evaluation of a Colts Standard Control Lens available from Colts Laboratories and a sample lens after both lenses are subjected to abrasion.

The Tumble Abrasion Test is used to test sample lenses that are within a power range of −0.50 to +0.50 diopters, have front (convex) curves within +/−0.25 diopters of control lenses, and have weight and diameter equivalent to the control lenses. The test is designed to provide comparative abrasion damage to sample and control lenses. Up to six test lenses and two control lenses may be tested in a single test run using the same abrasive mix. Test and control lenses are conditioned by exposing them to laboratory conditions for at least 24 hours before testing.

A new batch of abrasive media is prepared for each group of lenses that is tested using the Tumble Abrasion Test. A certain amount of each media component is counted or weighed, and the media components are combined in a hexagonal Rampart RB-2 Vinyl lined tumble barrel attached to a Rampart RBD-1 Tumble Machine. The media that are loaded into the tumble barrel are: 12 pieces of 3M Scrub pads cut into triangular shapes measuring 10.16×15.24±1.27 cm, 20 pieces of white polyurethane foam cut into triangular shapes measuring 10.16×15.24±1.27 cm, 459±15 grams of whole-wheat bran, 28±2 grams of #4 cube sawdust, 100±3 grams of 40/60 mesh grit-o-cob, 145±5 grams of 20/40 mesh grit-o-cob, 130±4 grams of white silica sand, and 72±3 grams of #12 emery. The media are mixed prior to sample abrasion by placing a cover over the tumble barrel filled with media and running the tumble machine at 29 rpm±1. After 10 minutes of mixing, the tumble machine is stopped and the material laying under the cover is pushed back into the tumble barrel.

An identifier is scribed on an appropriate side of the lenses no more than 10 mm from the edge of the lens. For convex side testing, the identifier is scribed on the concave side of the lens. The lenses are then washed. The initial haze of the standard control lenses and test lenses are read using a BYK-Gardener Haze-Gard Plus or equivalent. In order to test the convex side, a two-inch piece of black electrical tape is placed on the concave side of the lens so that only the convex side of the lens is abraded. The test samples and standards are weighed. The weight of each lens should be within 25% of the weight of each other lens. Electrical tape can be added to adjust the weight of individual lenses. The test samples and standards are placed randomly into the tumble barrel, which is tumbled for 20 minutes at 29 rpm±1. After tumbling is completed, the lenses are carefully removed from the tumble barrel, and the tape is removed from the lenses. The concave side of each lens is wiped with alcohol to remove any tape residue. The lenses are washed before reading the final haze and photographing the lenses.

The Tumble Average Ratio is calculated by finding the difference between the final haze value and the initial haze value for each standard lens and for each test lens, finding the average difference in haze value for the standard lenses (average standard lens haze gain) and the test lenses (average test lens haze gain), and dividing the average standard lens haze gain by the average test lens haze gain.

Five batches of polycarbonate lenses employing the example coating configuration were subjected to the Tumble Abrasion Test, and the convex-side Tumble Average Ratio of each batch was calculated. The convex-side Tumble Average Ratios of three commercial coating products on polycarbonate lenses, as determined by Colts Laboratories, are also shown as comparative examples. The transmittance percentages for the example coating configuration and the comparative examples were also determined. The results are shown in Table B.

TABLE B

| | Tumble | |
|---|---|---|
| Coating configuration | Average Ratio | Transmittance % |
| Example coating, batch 1 | 10.74 | 97.88 |
| Example coating, batch 2 | 8.12 | 97.66 |
| Example coating, batch 3 | 7.39 | 97.61 |
| Example coating, batch 4 | 9.35 | 97.73 |
| Example coating, batch 5 | 9.86 | 97.64 |
| Comparative example: | 4.5 | 97.1 |
| Product A | | |
| Comparative example: | 3.39 | 97.7 |
| Product B | | |
| Comparative example: | 4.33 | 97.83 |
| Product C | | |

The results in Table B show that each of the polycarbonate lenses with the example coating configuration had a Tumble Average Ratio greater than 7, while each of the comparative polycarbonate lens examples had a Tumble Average Ratio less than 5. Significantly, the mean Tumble Average Ratio for the five example coating configuration batches was about 9, more than twice the Tumble Average Ratio of the comparative examples.

The increase in abrasion resistance was achieved without substantial lowering of the lens transmittance. The use of IBAD during deposition of the high-index layers can result in a fully oxidized high-index material. Fully oxidized high-index materials exhibit higher transmittance compared to partially oxidized high-index materials.

The use of IBAD during deposition of the high-index layers permits modification of the inherent stress of those layers. The materials in the example coating configuration were chosen to have opposing inherent stresses: in particular, SiO₂ is compressively stressed, and ZrO₂ is tensile stressed or at least less compressively stressed than SiO₂. The inherent stresses of the example coating configuration's layers were configured to balance or at least partially balance the stresses within the AR stack, resulting in a very durable and impact resistant product.

The thickness of the hardening layer in the first example coating configuration is greater than the thickness of the hardening layers in many existing ophthalmic lens coating products. As the inherent stress of a layer is positively correlated with the thickness of the layer, there is a greater potential stress imbalance compared to those existing products. The inherent stress of the high-index layers was tuned using IBAD to balance the compressive stress of the SiO₂ layers in order to at least partially balance the overall stress of the coating A more stress-balanced coating typically exhibits better adhesion, abrasion resistance and impact resistance than an otherwise similar less stress-balanced coating.

Adhesion of lenses employing the example coating configuration was tested using the CHOCA and Salt Water Boil Tests with no failures. Impact strength of the lenses was also tested with no failures at 1927 inches of drop height, which was the maximum capability of the test instrument employed to test impact strength.

A second example coating configuration for a polycarbonate ophthalmic lens is shown in Table C. The structure of the example configuration is similar in many respects to the embodiment shown in FIG. 3, and the functional layer groups in the table are identified by corresponding reference numbers. Additional details regarding the layer materials, the thickness of each layer, the rate of deposit for each layer, whether IBAD is used during deposition of a layer, the ion energy of an RF ion source, and the process gas are provided in this example. The example also provides details for a clean step that can take place prior to deposition of the adhesor layer. During the clean step, the substrate can be contacted with ionized species of an inert gas, a reactive gas, or a mixture inert gas and reactive gas. In this example, the deposition process begins with the clean step and proceeds in order with deposition of the layers beginning with the adhesor layer 222 (nearest the ophthalmic lens) and ending with the topcoat layer 228 (furthest from the ophthalmic lens).

TABLE C

| Functional | | Thickness | | Use | Ion energy |
|---|---|---|---|---|---|
| layer group | Layer material | Rate of deposit | | IBAD? | Process gas |
| Topcoat 228 | Hydrophobic | 3 nm-25 nm | | No | N/A |
| | material system | 0.2 | nm/s | | |
| Antireflective | SiO₂ | 72 | nm | No | N/A |
| stack 226 | | 1.3 | nm/s | | |
| | ITO | 4 | nm | Yes | 100 eV |
| | (anti-static) | 0.05 | nm/s | | O₂ or Ar/O₂ |
| | Zr—Ta-oxide | 33 | nm | Yes | 100-300 eV |
| | | 0.45 | nm/s | | O₂ or Ar/O₂ |
| | Nb₂O₅ | 63 | nm | Yes | 100-300 eV |
| | | 0.30 | nm/s | | O₂ or Ar/O₂ |
| | Zr—Ta-oxide | 61 | nm | Yes | 100-300 eV |
| | | 0.45 | nm/s | | O₂ or Ar/O₂ |
| | SiO₂ | 52 | nm | No | N/A |
| | | 1.3 | nm/s | | |
| | Zr—Ta-oxide | 8 | nm | Yes | 100-300 eV |
| | | 0.30 | nm/s | | O₂ or Ar/O₂ |
| Hardening | SiO₂ | 150-300 | nm | Yes | 100-150 eV |
| layer 224 | | 1.3 | nm/s | | O₂ or Ar/O₂ |
| Adhesor layer | Mixture of Cr | 0.6-1.0 | nm | No | N/A |
| 222 | and SiO | 0.02 | nm/s | | |

| | | | | |
|---|---|---|---|---|
| Clean step | N/A | N/A | No | 60 eV |
| | | | | Argon |

Certain advantages and features of the example coating configuration shown in Table C will now be discussed. The advantages that will be discussed are believed to be at least partially attributable to one or more aspects of the example coating configuration disclosed above. For example, the use of IBAD during the deposition of the high-index layers can provide a very dense high-index material and also produces a very repeatable and controllable refractive index for the high-index layers. It has been observed that the abrasion resistance of a lens coated with the example coating configuration is substantially increased when compared to existing coated plastic lenses.

The use of IBAD during deposition of the high-index layers permits modification of the inherent stress of those layers. The materials in the example coating configuration were selected such that inherent stresses of adjacent layers are at least partially balanced. For example, the low index SiO₂ layers are compressively stressed, and the high index layers are tensile stressed or at least less compressively stressed than the SiO₂ layers. The inherent stresses of at least some layers of the example coating configuration can be increased using IBAD to balance or at least partially balance the stresses within the coating, resulting in a very durable and impact resistant product.

The thickness of the hardening layer in the second example coating configuration is greater than the thickness of the hardening layers in many existing ophthalmic lens coating products. Because the inherent stress of a layer is positively correlated with the thickness of the layer, there is a greater potential stress imbalance compared to the stress imbalances in existing products. In some embodiments, the inherent stress of the high-index layers is tuned using IBAD to at least partially balance the compressive stress of the SiO₂ layers in order to achieve a coating with a low level of overall stress. A more stress-balanced coating typically exhibits better adhesion, abrasion resistance and impact resistance than a less stress-balanced coating that is otherwise similar in many respects to the example coating configuration.

It is contemplated that the particular features, structures, or characteristics of any embodiments discussed herein may be combined in any suitable manner in one or more separate embodiments not expressly illustrated or described. For example, it is understood that a coating can include multiple antireflective stacks and that a combination of functional layer groups can combine to provide antireflective functionality. It is further understood that one or more features of the first example coating configuration can be combined with one or more features of the second example coating configuration, resulting in numerous additional lens coating embodiments, which are part of this disclosure.

In many cases, structures that are described or illustrated as unitary or contiguous can be separated while still performing the function(s) of the unitary structure. In many instances, structures that are described or illustrated as separate can be joined or combined while still performing the function(s) of the separated structures. It is further understood that the coatings disclosed herein may be used in at least some lens configurations and/or optical systems besides ophthalmic lenses.

It should be appreciated that in the above description of embodiments, various features are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that any claim require more features than are expressly recited in that claim. Moreover, any components, features, or steps illustrated and/or described in a particular embodiment herein can be applied to or used with any other embodiment(s). Thus, it is intended that the scope of the inventions herein disclosed should not be limited by the particular embodiments described above, but should be determined only by a fair reading of the claims that follow.

1. A physical vapor deposition process for forming a coating on a substrate of an ophthalmic lens in a vacuum deposition chamber, the process comprising:
depositing a hardening layer comprising a first thickness of low index material on the substrate;
depositing a multilayer interference stack having a plurality of low refractive index layers and a plurality of high refractive index layers on the substrate by:
depositing one or more of the plurality of high refractive index layers by contacting the substrate with a vapor phase pulse of one or more high refractive index source chemicals simultaneously while contacting the substrate with an energetic ion beam generated by an RF ion source; and
depositing each of the plurality of low refractive index layers by contacting the substrate with a vapor phase pulse of one or more low refractive index source chemicals, such that at least one of the deposited plurality of low refractive index layers is disposed adjacent to at least one of the deposited plurality of high refractive index layers;
wherein thicknesses of the plurality of high refractive index layers and the plurality of low refractive index layers are selected such that, when the multilayer interference stack is deposited on a surface of an ophthalmic lens, the luminous reflectance at the surface of the ophthalmic lens is less than or equal to about 2% using CIE illuminant D₆₅.

2. The process of claim 1, wherein the hardening layer is disposed between the multilayer interference stack and the ophthalmic lens.

3. The process of claim 2, wherein the first thickness is greater than or equal to about 150 nm.

4. The process of claim 2, further comprising depositing at least a portion of the hardening layer by contacting the substrate with a vapor phase pulse of one or more low refractive index source chemicals simultaneously while contacting the substrate with an energetic ion beam generated by the RF ion source.

5. The process of claim 1, wherein the one or more low refractive index source chemicals comprise a material having a visible light refractive index less than or equal to about 1.5.

6. The process of claim 1, wherein the one or more low refractive index source chemicals comprise silica or a mixture of silica and aluminum oxide.

7. The process of claim 1, wherein the one or more high refractive index source chemicals comprise one of zirconium oxide, niobium oxide, titanium oxide, tantalum oxide, cerium oxide, hafnium oxide, indium oxide doped with tin oxide, zinc oxide doped with aluminum oxide, or a mixture of zirconium oxide and tantalum oxide.

8. The process of claim 1, wherein the plurality of high refractive index layers comprises a plurality of adjacent thin film layers.

9. The process of claim 8, wherein the plurality of adjacent thin film layers comprises at least one layer that reduces or eliminates static charge buildup on the ophthalmic lens.

10. The process of claim 9, wherein the at least one layer that reduces or eliminates static charge buildup comprises indium oxide doped with tin oxide, zinc oxide doped with aluminum oxide, another transparent conductive oxide, or a combination thereof.

11-12. (canceled)

13. The process of claim 1, wherein contacting the substrate with an energetic ion beam comprises directing one or more ionized species of oxygen towards the substrate.

14-24. (canceled)

25. A physical vapor deposition process for forming a coating on a substrate of an ophthalmic lens in a vacuum deposition chamber, the process comprising:
depositing a multilayer interference stack having a plurality of low refractive index layers and a plurality of high refractive index layers on the substrate by:
depositing one or more of the plurality of high refractive index layers by contacting the substrate with a vapor phase pulse of niobium source chemical simultaneously while contacting the substrate with an energetic ion beam generated by an RF ion source; and
depositing each of the plurality of low refractive index layers by contacting the substrate with a vapor phase pulse of one or more low refractive index source chemicals, such that at least one of the plurality of low refractive index layers is disposed adjacent to at least one of the plurality of high refractive index layers;
wherein the one or more of the plurality of high refractive index layers comprises a layer of substantially stoichiometric Nb₂O₅.

26. The process of claim 25, further comprising depositing at least one of the plurality of high refractive index layers by contacting the substrate with a metal source chemical comprising at least one metal selected from the group consisting of titanium (Ti), zirconium (Zr), hafnium (Hf), vanadium (V), tantalum (Ta), chromium (Cr), and cerium (Ce).

27. The process of claim 25, wherein the niobium source chemical is selected from the group consisting of niobium halides, niobium oxides, and niobium organic compounds.

28. The process of claim 25, wherein an ion energy level of the energetic ion beam is varied during deposition of one or more of the plurality of high refractive index layers.

29-30. (canceled)

31. The process of claim 25, wherein the plurality of high refractive index layers comprises two or more layers disposed immediately adjacent to one another.

32. (canceled)

33. The process of claim 25, further comprising depositing a hardening layer of low refractive index material having a thickness greater than or equal to 150 nm between the multilayer interference stack and the substrate.

34. The process of claim 33, wherein depositing the hardening layer comprises:
contacting the substrate with a vapor phase pulse of one or more low refractive index source chemicals; and
simultaneously while contacting the substrate with the vapor phase pulse of one or more low refractive index source chemicals, contacting the substrate with an energetic ion beam generated by the RF ion source.

35. The process of claim 34, further comprising adjusting the energy level of the energetic ion beam during deposition of the hardening layer such that inherent stress at an upper interface of the hardening layer at least partially balances inherent stress in a layer adjacent to the upper interface

36-47. (canceled)

48. A physical vapor deposition process for forming a coating on a substrate of an ophthalmic lens in a vacuum deposition chamber, the process comprising:
depositing a first plurality of thin film layers on the substrate, each of the first plurality of thin film layers being inherently negatively stressed; and
depositing a second plurality of thin film layers on the substrate, the second plurality of thin film layers having an increased level of inherent stress compared to the first plurality of thin film layers, wherein each of the second plurality of layers is deposited by:
contacting the substrate with a vapor phase pulse of a metal source chemical;
simultaneously while contacting the substrate with the vapor phase pulse of a metal source chemical, contacting the substrate with an energetic ion beam; and
adjusting the energy level of the energetic ion beam during deposition of one or more of the second plurality of thin film layers such that a substantial density gradient is created between an upper interface and a lower interface of the one or more of the second plurality of thin film layers.

49-50. (canceled)

51. The process of claim 48, wherein the energetic ion beam is generated by an RF ion source.

52-55. (canceled)

56. The process of claim 48, wherein the one or more of the second plurality of thin film layers are configured such that inherent stress at the upper interface of the one or more of the second plurality of thin film layers at least partially balances inherent stress in a layer adjacent to the upper interface.

57. The process of claim 56, wherein the one or more of the second plurality of thin film layers are configured such that inherent stress at the lower interface of the one or more of the second plurality of thin film layers at least partially balances inherent stress in a layer adjacent to the lower interface.

58. The process of claim 48, wherein depositing the first plurality of thin film layers on the substrate comprises, for at least one of the first plurality of thin film layers:
contacting the substrate with a vapor phase pulse of silica; and
simultaneously while contacting the substrate with the vapor phase pulse of silica, contacting the substrate with an energetic ion beam;
wherein the energy level of the energetic ion beam is selected such that inherent stresses in the at least one of the first plurality of thin film layers is tuned to at least partially balance inherent stresses in the second plurality of thin film layers.

59-64. (canceled)
